(19) United States
(12) Patent Application Publication
(10) Pub. No.: US 2026/0165143 A1
(43) Pub. Date: Jun. 11, 2026

(54) THERMALLY CONTROLLED SWITCH EMBEDDED ON EMBEDDED MULTI-DIE INTERCONNECT BRIDGE PACKAGING FOR PRODUCT MINIATURIZATION

(71) Applicant: Intel Corporation, Santa Clara, CA (US)

(72) Inventors: Azniza ABD AZIZ, Pulau Penang (MY); Yong Chun GWEE, Pulau Pinang (MY); Jackson Chung Peng KONG, Pulau Pinang (MY); Eu Jinn NG, Pulau Pinang (MY); Tze Huat TEE, Klang (MY)

(21) Appl. No.: 18/970,956

(22) Filed: Dec. 6, 2024

(51) Int. Cl. H01L 23/62; H01L 23/538; H01L 25/16; H10D 1/47

(52) U.S. Cl. CPC H10W 42/80; H10W 70/611; H10W 70/65; H10W 90/00; H10D 1/47

(57) ABSTRACT

The present disclosure generally relates to a device including one or more dies on a substrate, and a switch operably coupled to the one or more dies, wherein the switch is embedded in a bridge, wherein the bridge is embedded in the substrate, and wherein the switch is operable to select which of the one or more dies to be operated.

### BACKGROUND

In a semiconductor device, traditionally, all function (or feature) signal pins may be required to be routed out and the quantity of signal pins exhibits cyclical increases with the chiplet technology (e.g., more dies) as depicted in the table shown in FIG. 1B for function/feature B (also see FIG. 1A left image). As a result, the signal routing in the package area leads to a higher space requirement, which in turn contributes to an increase in package cost. Furthermore, certain function/feature may be utilized only when necessary and hence the signal pins may not be used to their full potential.

To address the above, traditional approaches may include having a ball-out function/feature of the signal pins or adding a multiplexer (MUX) in silicon to select the function/feature of the signal pins.

In the approach of using the ball-out for every signal for every function/feature suffers a trade-off in the growth of the package size, this also indirectly increases the package cost. Besides, this approach may suffer routing congestion, which tends to degrade the signal integrity performance in terms of crosstalk. The alternative approach, as mentioned above, may be to implement the MUX in silicon to prioritize feature/function selection of the signals. However, the number of functions/features continue to increase with chiplet technology, which may then lead to similar issues with package size growth and routing congestion, as numerous signals need to be routed out (and hence more signal pins needed).

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the present disclosure. The dimensions of the various features or elements may be arbitrarily expanded or reduced for clarity. In the following description, various aspects of the present disclosure are described with reference to the following drawings, in which:

FIG. 1A shows a cross-sectional view of an example of a traditional device having full features routing versus a device of the present disclosure configured with selected features or function routing;

FIG. 1B shows the quantity of signal pins for a function/feature based on product segment;

FIG. 2A shows the traditional architecture of a multiplexer in silicon;

FIG. 2B shows the same architecture of a multiplexer in silicon of FIG. 2A with the exception of a thermally controlled switch embedded on an embedded multi-die interconnect bridge (EMIB) package;

FIG. 3 shows a device of the present disclosure, particularly the embedded multi-die interconnect bridge (EMIB), and use of Intel's three-dimensional (3D) packaging technology;

FIG. 4 shows a device of the present disclosure, particularly the thermally controlled switch in the EMIB packaging; and

FIG. 5 shows a device of the present disclosure, particularly the same thermally controlled switch shown in FIG. 4 and the details of the interconnect level from silicon (e.g., a die) to package substrate to the printed circuit board (PCB).

### DETAILED DESCRIPTION

The following detailed description refers to the accompanying drawings that show, by way of illustration, specific details and aspects in which the present disclosure may be practiced. These aspects are described in sufficient detail to enable those skilled in the art to practice the present disclosure. Various aspects are provided for devices, and various aspects are provided for methods. It will be understood that the basic properties of the devices also hold for the methods and vice versa. Other aspects may be utilized and structural, and logical changes may be made without departing from the scope of the present disclosure. The various aspects are not necessarily mutually exclusive, as some aspects may be combined with one or more other aspects to form new aspects.

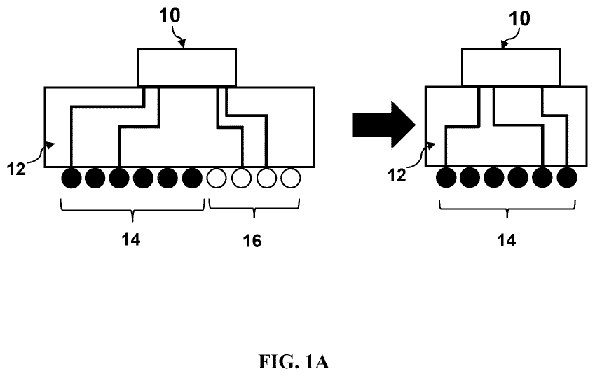

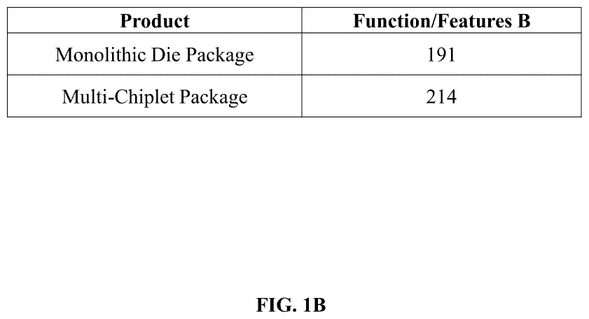

The present disclosure generally relates to a device. The device may help to address and/or circumvent any of the issues and limitations mentioned above. The device may include a switch, which may be thermally controllable via an electrical input, embedded in a substrate (e.g., a package substrate). The switch may be electrically (and/or operably) coupled to a controller in the device. The switch is operable to toggle operation of the device. If the device includes a controller, the switch and the controller may be co-operable to toggle operation of the device. That is to say, the device, which includes such a switch, and optionally a controller, is able to render one or more dies to execute a function or a feature of the device when required while one or more other dies remain idle so that another function or feature of the device is not activated or utilized (when not required). The device, with such a switch, is able to operate in this manner, and with only one set of ball contacts, i.e., only one set of ball contacts is needed, for the device to carry out each of the different functions or features (when required). This is advantageous over traditional devices that have an architecture containing multiple sets of ball contacts just for carrying out each of the different functions or features. In such traditional devices, each set of ball contacts may correspond to one function or one feature, hence different sets of ball contacts are then required. FIG. 1A shows a cross-sectional view of an example of such a traditional device having full features routing versus a device of the present disclosure configured with selectable features or function routing.

FIG. 1A (left image) shows an example of a traditional device having a die 10 configured on a substrate 12. The substrate 12 may be a package substrate. Two sets of ball contacts 14, 16 are configured at a bottom surface of the substrate 12. The two sets of ball contacts 14, 16 may be distal from and are electrically coupled to the die 10 via one or more metal lines (i.e., black lines connecting die 10 and the ball contacts 14, 16). One set of the ball contacts 14 is configured to relay signal to and from the die 10 so as to have the device carry out a first function or a first feature. The other set of ball contacts 16 is configured to relay signal to and from the die 10 so as to have the device carry out a second function or a second feature. The first function (first feature) and the second function (second feature) are different. In other words, the traditional device includes different sets of ball contacts 14, 16 just to accommodate different functions and features. FIG. 1A (right image) shows a device of the present disclosure. The device includes, as mentioned above, the switch (not shown). With the switch, advantageously, the device can operate using just one set of ball contacts 14 for carrying either the first function (first feature) or the second function (second feature). In other words, the device of the present disclosure can be toggled between two modes of operation (execution of either function can be selected) even with the sets of ball contacts reduced (to just one set of ball contacts). This in turn means that, for the device of the present disclosure, (i) crosstalk may be reduced since wider spacing becomes available due to more routing area at silicon bump and package ball-grid-array (BGA) areas (since less ball contacts are included), (ii) substrate (e.g., package substrate) size may be reduced-with the selection of features enabled (even with less ball contacts), large package size is no longer required to route all the signals on package, and (iii) cost reduction given that smaller package dimensions contribute to decrease in cost.

FIG. 1B shows the quantity of signal pins for a function/feature based on product segment (e.g., monolithic die package, multi-chiplet package). Said differently, FIG. 1B identifies the number of signal pins (ball contacts) that may be needed to carry out the second function or second feature mentioned in relation to FIG. 1A. However, with the present device, it can be seen that the number of signal pins can be considerably reduced (as shown in right image of FIG. 1A), freeing up space on the package substrate and lowering cost, and with selection of functions or features enabled.

Advantageously, with respect to FIG. 1A and FIG. 1B, the present device, with a reduction in the package substrate size (e.g., by removing the set of ball contacts 16 (removing 10% to 12% of the ball contacts)) may enhance space utilization and cost efficiency in the package substrate while still preserving integrity and reliability of the device.

As mentioned above, the device of the present disclosure may include a switch. The switch may include a parallel plates structure within a bridge embedded (or partially embedded) in a substrate (e.g., package substrate), wherein the bridge, and the switch, may be electrically coupled to the one or more dies via one or more interconnects. As the bridge may serve as a connection between one die and another die, the bridge may be termed in the present disclosure as an “interconnect bridge”. The one or more interconnects may be embedded (or partially embedded) in the substrate (or in the bridge). The parallel plates structure may include a first plate (e.g., an anode) that may be configured proximal to a ball-grid-array (BGA). The first plate may be electrically coupled to the BGA via the substrate, wherein the BGA may be configured as input contact points. The parallel plates structure may include a second plate (e.g., a cathode) configured opposite to the first plate. The second plate may be configured distal from the BGA. The first plate and the second plate may be embedded in the bridge and may have one or more interconnects that may be configured as output to one or more bump(s) which the one or more dies may be electrically coupled to.

To more readily understand and put into practical effect the present disclosure, the device and method, and particular aspects will now be described by way of examples and not limitations, and with reference to the drawings. For the sake of brevity, duplicate descriptions of features and properties may be omitted.

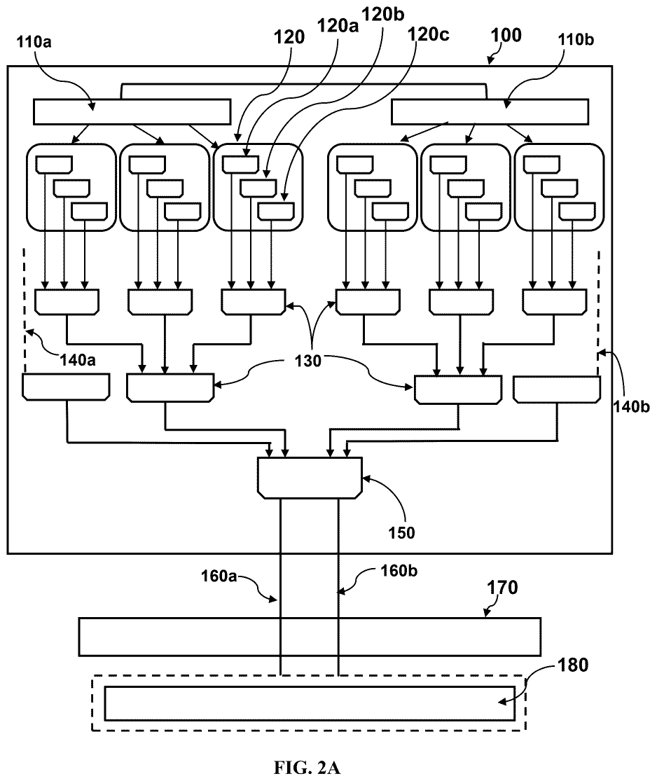

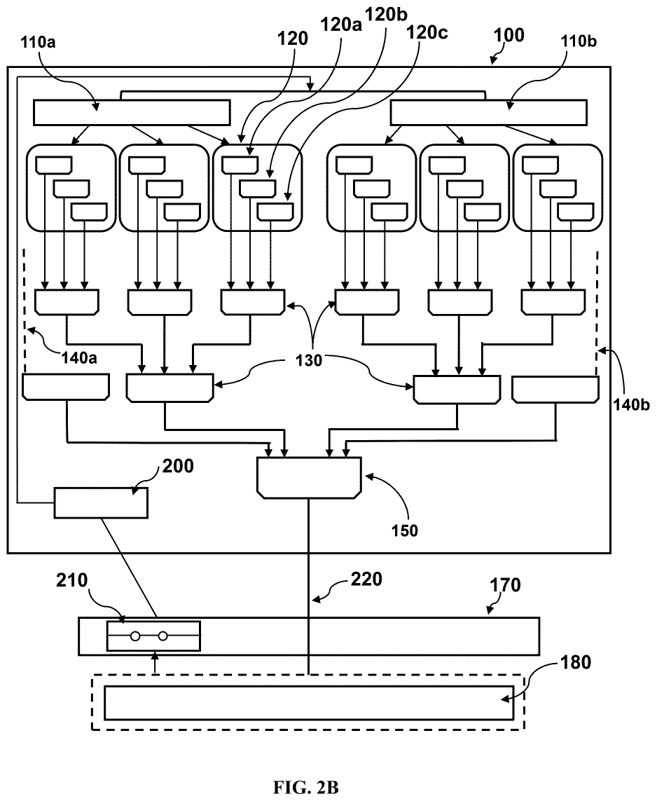

FIG. 2A shows an example of a traditional device (e.g., a multiplexer in silicon). The multiplexer is operable to execute two different functions 110a, 110b. Each of the two different functions 110a, 110b may be operably associated with one or more sets of dies 120. Each of the one or more sets of dies 120 may include one or more dies 120a, 120b, 120c. The one or more dies 120a, 120b, 120c may each be a unit level multiplexer (ULM). The one or more dies 120a, 120b, 120c may be electrically coupled to one or more partition level multiplexer 130 (PLM). 140a, 140b denotes electrical connections to N+1 set of dies (e.g., N+1 set of partition level multiplexer 130), wherein N is a whole number, meaning to say, there may be many more set of dies 120. The one or more partition level multiplexer 130 may be electrically coupled to a cluster level multiplexer 150 (CLM). The cluster level multiplexer 150 may be electrically coupled via one or more sets of ball contacts 160a, 160b to a substrate 170 (e.g., package substrate) and a circuit board 180 (e.g., a printed circuit board). For example, the ball contacts 160a, 160b may each include N+1 signal pins, wherein N is a whole number. Ball contacts 160a, 160b may correspond to functions 110a, 110b, respectively. That is to say, in such a traditional device, different sets of ball contacts 160a, 160b are needed to accommodate different functions, i.e., the number of sets of ball contacts depends on the number of functions. The ball contacts 160a, 160b may form the BGA. Observably, such a traditional device requires more routing area and a higher number of BGA than a device of the present disclosure, shown in FIG. 2B (wherein the package substrate routing requirements can be based on customer needs).

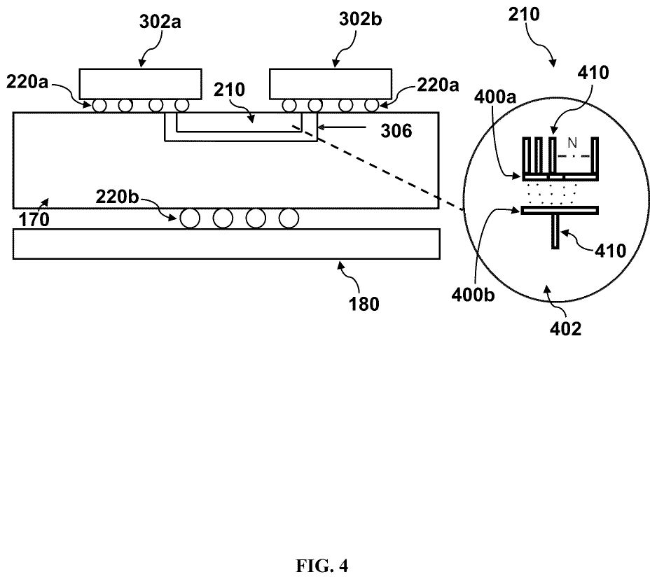

FIG. 2B shows the same architecture of the device (e.g., a multiplexer in silicon) of FIG. 2A with the exception of a thermally controlled switch 210 embedded within a bridge that may be embedded in the substrate 170. The same reference numerals are used to refer to the same elements and hence not reiterated for brevity. The bridge may be referred to as an “embedded multi-die interconnect bridge”, abbreviated “EMIB”. The switch 210 may be operably coupled to (and electrically coupled) to a controller 200. The switch 210 and controller 200 may be co-operable to select either a first function (first feature) or a second function (a second feature) to be carried out, utilizing the same set of ball contacts 220, hence reducing the sets of ball contacts (e.g., from two sets to one set). With less ball contacts used and selection of the function/feature enabled, space is freed up. Said differently, the present device (e.g., the multiplexer) is introduced with the thermally controlled switch 210 in the EMIB for lesser signal pins (e.g., ball contacts 220) with features selection capabilities enabled compared to the traditional device in FIG. 2A. The switch 210 may be controlled by an electrical current to toggle to the signal pins. Advantageously, the device of the present disclosure can accommodate N+1 signal pins even with the BGA quantity reduction, wherein N denotes a whole number. More details on the switch 210 is described with respect to FIG. 4 further below.

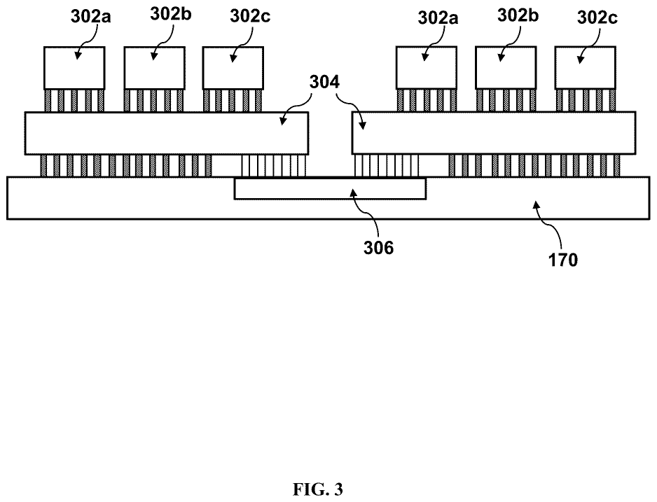

FIG. 3 shows a device of the present disclosure, particularly the embedded multi-die interconnect bridge (EMIB) and use of Intel's 3D packaging technology, to construct the planar denser multi-die packages. For brevity, the EMIB may be referred to as a bridge 306. The bridge 306 may be embedded (or partially embedded) in the substrate 170 (e.g., package substrate). The bridge 306 may act as an interconnect between dies 302a, 302b, 302c on (or electrically coupled to) the substrate 170. The dies 302a, 302b, 302c may be configured on one or more base dies 304, which the bridge 306 is coupled directly (and electrically) to. Particularly, the EMIB is a technology for constructing planar dense multi-chip packages. The EMIB can include thin silicon pieces with multiple layers of back-end-of-line interconnects within a substrate (e.g., an organic substrate), allowing high density die-to-die connections as shown in FIG. 3. The thicker black lines connecting the dies 302a, 302b, 302c and the base dies 304 as well as the base dies 304 to the substrate 170 denote for metal lines (or interconnects) electrically connecting these elements. The thinner black lines connecting the base dies 304 to the bridge 306 denote for metal lines (or interconnects) electrically connecting these elements.

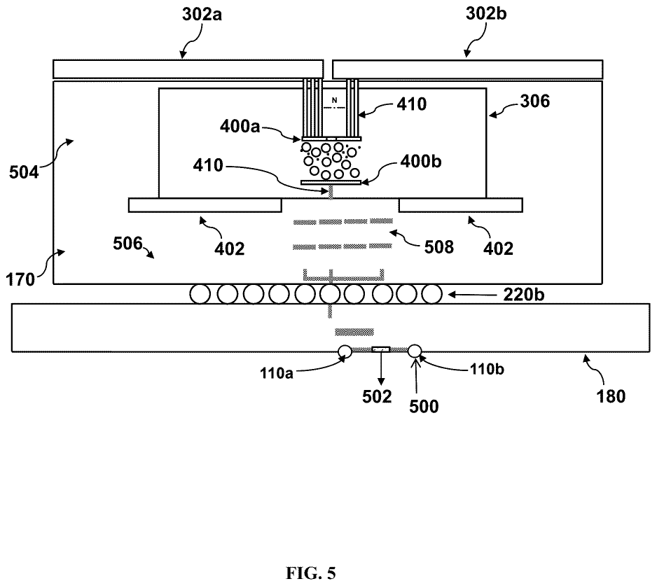

FIG. 4 shows a device of the present disclosure, particularly the thermally controlled switch 210 in the bridge 306 that is embedded in the substrate 170. The dies 302a, 302b may be configured for different functions (e.g., a first function and a second function) to be carried out, wherein selection of which of the dies 302a, 302b to operate may be carried out via the switch 210. The dies 302a, 302b may be electrically coupled to the substrate 170 via bumps 220a (e.g., micro-bumps or silicon bumps) and the substrate 170 may be electrically coupled to a circuit board 180 (e.g., a printed circuit board) via ball contacts 220b. The inset depicts the architecture of the switch 210, showing the parallel plates structure (e.g., a cathode 400a and an anode 400b). Each of the plates may be electrically coupled to one or more interconnects 410. Particularly, the thermally controlled switch 210 is implemented in the substrate 170 through the EMIB. The switch 210, or more specifically the parallel plates structure, may utilise the bulk silicon of the EMIB to perform the switching function (selection of first function or second function to be carried out). This semiconductor material, e.g., the silicon, transitions to effective conductive materials with temperature change. To provide a better understanding, the switch 210 may be constructed from two plates configured parallel to each other, one as the anode 400b and the other as the cathode 400a. The switch 210 may be considered as part of a circuit with input from the circuit board 180. A high current may be supplied to the circuit (through one or more input contacts (shown in FIG. 5) at the circuit board 180), which raises the temperature of the parallel plates, as the parallel plates may include or may be formed of a thermally conductive material. When temperature increases, electrons (denoted by the small dots in the inset) may flow from anode 400b to cathode 400a as an example, rendering the conduction of electricity out from the switch 210 to an output (e.g., one of dies 302a, 302b). For example, the output may be connected to a die or a controller that is co-operable with the switch 210 to control whether the first function or the second function is to be carried out. As a further example, the first function/feature can be a default function of the device. While current is supplied to a contact input at the circuit board 180, the switch 210 is thermally activated to render the second function/feature to be carried out (while the first function/feature gets turned off). As the switch 210 involves a change in temperature to work, the switch in the present disclosure is referred to as a thermally controlled (or thermally controllable) switch. The symbol “N” together with the symbol “-·-” denote for N number of interconnects 410 electrically coupled to the cathode 400a, wherein N may be a whole number.

FIG. 5 shows a device of the present disclosure, particularly the same thermally controlled switch 210 shown in FIG. 4 and the details of the interconnect level 504 from silicon (e.g., dies 302a, 302b) to substrate 170 to the circuit board 180 (e.g., printed circuit board). It can be seen that the switch 210 is embedded in the bridge 306 (EMIB). The bridge 306 serves as an interconnect between the dies 302a, 302b. The switch 210 may include two plates, one anode 400b and the other being a cathode 400a. The cathode 400a may be electrically coupled to the one or more dies 302a, 302b via one or more interconnects 410. The anode 400b may be electrically coupled to a set of ball contacts 220b (BGA) via one or more substrate interconnects 508 in the substrate 170. The first plate (e.g., anode 400b) may be connected to a BGA (as an input) through the substrate 170 via an interconnect 410, while the second plate (e.g., cathode 400a) may be embedded within the bridge 306 with one or more interconnects 410 as output to the bump(s) (not shown). As an example, to illustrate how the switch 210 works, by default the first function/feature 110a may be routed end to end from silicon (e.g., dies 302a, 302b) to substrate 170 (e.g., package substrate) to circuit board 180. If a user chooses to select the second function/feature 110b, then the first step is to depopulate (e.g., remove or disconnect) a resistor 502 connected to the one contact input associated with the first function/feature 110a and populate (e.g., connect or physically assemble or mount) the resistor 502 to be connected to the other contact input associated with the second function/feature 110b. After that, a current 500 may be injected as a signal and the switch 210 may be activated and toggled to effect the second function/feature 110b. 402 denotes a metal line of the substrate 170. In other words, the resistor 502 may be considered as a controller to the switch 210, i.e., the switch 210 and the resistor 502 may be co-operable to toggle the device to carry out either the first function/feature 110a or second function/feature 110b. The white dots between the anode 400b and the cathode 400a denote electrons flowing from the anode 400b to cathode 400a as temperature of switch 210 increases due to the electrical current supplied for activating the second function/feature 110b. In various examples, the one input contact associated with the first function 110a (e.g., default function) may be supplied with an electrical current, and/or the other input contact associated with the second function 110b may be discharged of electrical current, to render the switch operable to have the device carry out the first function. In various examples, the one input contact associated with the first function 110a may be discharged of electrical current, and/or the other input contact associated with the second function 110b may be supplied with an electrical current, to render the switch operable to have the device carry out the second function. 504 and 506 denote, respectively, the vertical and horizontal interconnects in the substrate 170. 508 denotes sets of interconnects that form the circuitry for relaying an electrical current between the circuit board 180 and the switch 210. As the sets of interconnects 508 may have to accommodate a high current, these sets of interconnects 508 may have high metal density for better current carrying capability (to avoid any reliability issue). The anode 400b and the cathode 400a may be formed of any suitable thermally conductive material that works in the manner described above, that is, to allow the device to toggle between carrying out different functions, and to allow electrons to flow from anode 400b to cathode 400a when temperature increases to change from a first function to carrying out a second function.

Additional aspects of the disclosure are demonstrated by way of non-limiting examples below.

Example 1 may include a device. In various aspects and examples, the device may include one or more dies on a substrate, and a switch operably coupled to the one or more dies, wherein the switch may be embedded (or partially embedded) in a bridge, wherein the bridge may be embedded (or partially embedded) in the substrate, and wherein the switch may be operable to select which of the one or more dies to be operated. In various examples, the switch may be electrically coupled to the one or more dies. In various examples, the device may include, optionally, a controller electrically coupled to the one or more dies. In various examples, the switch may be operably coupled to the controller. In various examples, the switch and the controller may be co-operable to select which of the one or more dies to be operated.

Example 2 may include the device of example 1 and/or any other example disclosed herein, wherein the substrate may be a package substrate.

Example 3 may include the device of example 1 and/or any other example disclosed herein, wherein the one or more dies may be formed on one or more base dies.

Example 4 may include the device of example 3 and/or any other example disclosed herein, wherein the one or more dies may be electrically coupled to the one or more base dies via one or more interconnects.

Example 5 may include the device of example 3 and/or any other example disclosed herein, wherein the one or more base dies may be formed on the substrate.

Example 6 may include the device of example 3 and/or any other example disclosed herein, wherein the one or more base dies may be electrically coupled to the substrate via one or more interconnects.

Example 7 may include the method of example 3 and/or any other example disclosed herein, wherein the one or more base dies may be electrically coupled to the bridge via one or more interconnects.

Example 8 may include the device of example 1 and/or any other example disclosed herein, wherein the one or more dies may be electrically coupled to the switch via one or more interconnects.

Example 9 may include the device of example 1 and/or any other example disclosed herein, further including a set of ball contacts configured between the substrate and a circuit board, wherein the set of ball contacts may electrically couple the substrate to the circuit board.

Example 10 may include the device of example 9 and/or any other example disclosed herein, wherein the switch may include an anode and a cathode, wherein the anode may be electrically coupled to one or more of the set of ball contacts and the cathode may be electrically coupled to the one or more dies, wherein the anode may be electrically coupled to one or more of the set of ball contacts via one or more interconnects, and wherein the cathode may be electrically coupled to the one or more dies via one or more interconnects.

Example 11 may include the device of example 9 and/or any other example disclosed herein, wherein the circuit board may include a resistor embedded (or partially embedded) in the circuit board.

Example 12 may include the device of example 11 and/or any other example disclosed herein, wherein the resistor may be electrically coupled to two input contacts, one input contact associated with a first function and the other input contact associated with a second function.

Example 13 may include the device of example 12 and/or any other example disclosed herein, wherein the one input contact associated with the first function may be supplied with an electrical current, and/or the other input contact associated with the second function may be discharged of electrical current, to render the switch operable to have the device carry out the first function. The other input contact may be first discharged of electrical current, the one input contact may then be supplied (e.g., charged) with electrical current. If a controller is included, the switch and the controller may be co-operable to have the device carry out the first function.

Example 14 may include the device of example 12 and/or any other example disclosed herein, wherein the one input contact associated with the first function may be discharged of electrical current, and/or the other input contact associated with the second function may be supplied with an electrical current, to render the switch operable to have the device carry out the second function. The one input contact may be first discharged of electrical current, the other input contact may then be supplied (e.g., charged) with electrical current. If a controller is included, the switch and the controller may be co-operable to have the device carry out the second function.

Example 15 may include the device of example 12 and/or any other example disclosed herein, wherein the resistor may be electrically coupled to the set of ball contacts via an interconnect embedded in the circuit board.

Example 16 may include the device of example 1 and/or any other example disclosed herein, wherein the bridge may be configured as an interconnect between one die and another die.

Example 17 may include the device of example 9 and/or any other example disclosed herein, wherein the bridge may be electrically coupled to the set of ball contacts via one or more interconnects embedded in the substrate.

Example 18 may include the device of example 1 and/or any other example disclosed herein, wherein the device may be a multiplexer.

Example 19 may include a substrate of the present disclosure. In various aspects and examples, the substrate may be suitable for selecting (or operable to select) a function to be carried out by a device. In various aspects and examples, the substrate may include an interconnect which may be operable as a bridge electrically coupled to one or more dies formable on the substrate, and a switch operably coupled to the one or more dies, wherein the switch may be embedded in the bridge, wherein the bridge may be embedded in the substrate, wherein the switch may be operable to select which of the one or more dies to be operated so as to carry out the function. In various examples, the switch may be electrically coupled to the one or more dies. In various examples, the switch, optionally, may be operably coupled to a controller. In various examples, the switch and the controller may be co-operable to select which of the one or more dies to be operated so as to carry out the function. In various examples, the function may be the first function or the second function as mentioned above.

Example 20 may include the device of example 19 and/or any other example disclosed herein, wherein the substrate is a package substrate.

The term “comprising” shall be understood to have a broad meaning similar to the term “including” and will be understood to imply the inclusion of a stated integer or operation or group of integers or operations but not the exclusion of any other integer or operation or group of integers or operations. This definition also applies to variations on the term “comprising” such as “comprise” and “comprises”.

While the present disclosure has been particularly shown and described with reference to specific aspects, it should be understood by persons skilled in the art that various changes in form and detail may be made therein without departing from the scope of the present disclosure as defined by the appended claims. The scope of the present disclosure is thus indicated by the appended claims and all changes which come within the meaning and range of equivalency of the claims are therefore intended to be embraced.

What is claimed is:

1. A device comprising:
one or more dies on a substrate; and
a switch operably coupled to the one or more dies;
wherein the switch is embedded in a bridge, wherein the bridge is embedded in the substrate, and wherein the switch is operable to select which of the one or more dies to be operated.

2. The device of claim 1, wherein the substrate is a package substrate.

3. The device of claim 1, wherein the one or more dies are formed on one or more base dies.

4. The device of claim 3, wherein the one or more dies are electrically coupled to the one or more base dies via one or more interconnects.

5. The device of claim 3, wherein the one or more base dies are formed on the substrate.

6. The device of claim 3, wherein the one or more base dies are electrically coupled to the substrate via one or more interconnects.

7. The device of claim 3, wherein the one or more base dies are electrically coupled to the bridge via one or more interconnects.

8. The device of claim 1, wherein the one or more dies are electrically coupled to the switch via one or more interconnects.

9. The device of claim 1, further comprising a set of ball contacts configured between the substrate and a circuit board, wherein the set of ball contacts electrically couple the substrate to the circuit board.

10. The device of claim 9, wherein the switch comprises an anode and a cathode, wherein the anode is electrically coupled to one or more of the set of ball contacts and the cathode is electrically coupled to the one or more dies, wherein the anode is electrically coupled to one or more of the set of ball contacts via one or more interconnects, and wherein the cathode is electrically coupled to the one or more dies via one or more interconnects.

11. The device of claim 9, wherein the circuit board comprises a resistor embedded in the circuit board.

12. The device of claim 11, wherein the resistor is electrically coupled to two input contacts, one input contact associated with a first function and the other input contact associated with a second function.

13. The device of claim 12, wherein the one input contact associated with the first function is supplied with an electrical current, and/or the other input contact associated with the second function is discharged of electrical current, to render the switch operable to have the device carry out the first function.

14. The device of claim 12, wherein the one input contact associated with the first function is discharged of electrical current, and/or the other input contact associated with the second function is supplied with an electrical current, to render the switch operable to have the device carry out the second function.

15. The device of claim 12, wherein the resistor is electrically coupled to the set of ball contacts via an interconnect embedded in the circuit board.

16. The device of claim 1, wherein the bridge is configured as an interconnect between one die and another die.

17. The device of claim 9, wherein the bridge is electrically coupled to the set of ball contacts via one or more interconnects embedded in the substrate.

18. The device of claim 1, wherein the device is a multiplexer.

19. A substrate for selecting a function to be carried out by a device, the substrate comprising:
an interconnect which is operable as a bridge electrically coupled to one or more dies formable on the substrate; and
a switch operably coupled to the one or more dies,
wherein the switch is embedded in the bridge, wherein the bridge is embedded in the substrate, wherein the switch is operable to select the function.

20. The substrate of claim 19, wherein the substrate is a package substrate.
